(19) United States
(12) Patent Application Publication
(10) Pub. No.: US 2017/0018483 A1
(43) Pub. Date: Jan. 19, 2017

(54) INTEGRATED CIRCUIT CHIP FABRICATION LEADFRAME

(71) Applicant: TEXAS INSTRUMENTS INCORPORATED, DALLAS, TX (US)

(72) Inventors: Robert L. Pitts, Dallas, TX (US); Leslie E. Stark, Rowlett, TX (US)

(21) Appl. No.: 14/985,737

(22) Filed: Dec. 31, 2015

Related U.S. Application Data
(60) Provisional application No. 62/193,978, filed on Jul. 17, 2015.

(51) Int. Cl. H01L 23/495; H01L 23/00

(52) U.S. Cl. CPC H01L 23/4951; H01L 23/49537; H01L 23/562

(57) ABSTRACT

One example includes a conductive leadframe configured to couple to an integrated circuit (IC) chip die on a contact surface of the IC chip die. The conductive leadframe includes a plurality of chip-pin connections configured to facilitate conductive coupling to bond pads of the IC chip die via conductive lead wires. The conductive leadframe also includes a support beam that extends across the conductive leadframe along the contact surface of the IC chip die to enable support of the IC chip die to the conductive leadframe at a plurality of support locations during testing of the IC associated with the IC chip die.

### CROSS-REFERENCE TO RELATED APPLICATION

This application claims the benefit of U.S. Provisional Application No. 62/193,978, filed Jul. 17, 2015, and entitled CHIP ON LEAD PACKAGE LEADFRAME WHICH FACILITATES PARALLEL TESTING ON STRIP HANDLERS, which is incorporated herein in its entirety.

### TECHNICAL FIELD

This disclosure relates generally to electronic system fabrication, and more specifically to an integrated circuit chip fabrication leadframe.

### BACKGROUND

Integrated circuits (ICs) can be fabricated in a process in which a wafer is cut into multiple dice that are each provided in an IC package, with the IC package including conductive chip-pins that provide inputs and outputs for the IC. The conductive chip-pins can be trimmed from a conductive leadframe on which the dice are provided. During an IC packaging process, the ICs can be engineered for flexible package trim and form followed by a massively parallel test using strip handlers. The parallel testing of the ICs occurs after the conductive-chip pins are trimmed from the conductive leadframe to ensure electrical isolation of the chip-pins with respect to each other. As an example, in some IC fabrication processes, only a single chip-pin can remain coupled to the conductive leadframe during a test, with such single chip-pin being trimmed from the conductive leadframe after the test to remove the resultant IC chip from the conductive leadframe. For example, the single conductive leadframe can correspond to a ground connection for the IC, such that the conductive leadframe can be grounded during the parallel test.

### SUMMARY

One example includes a conductive leadframe configured to couple to an integrated circuit (IC) chip die on a contact surface of the IC chip die. The conductive leadframe includes a plurality of chip-pin connections configured to conductively couple to bond pads of the IC chip die via conductive lead wires. The conductive leadframe also includes a support beam that extends across the conductive leadframe along the contact surface of the IC chip die to enable support of the IC chip die to the conductive leadframe at a plurality of support locations during testing of the IC associated with the IC chip die.

Another example includes a conductive leadframe configured to couple to an IC chip die on a contact surface of the IC chip die. The conductive leadframe includes a plurality of chip-pin connections configured to conductively couple to bond pads of the IC chip die via conductive lead wires. The conductive leadframe further includes a support beam that extends across the conductive leadframe along the contact surface of the IC chip die between a first edge of the IC chip die and a second edge of the IC chip die opposite the first edge to enable support of the IC chip die to the conductive leadframe at a junction of the contact surface and the first edge and at a junction of the contact surface and the second edge during testing of the IC associated with the IC chip die.

Another example includes a leadframe system comprising a plurality of conductive leadframes that are arranged in an array and are fabricated from a unitary conductive material with respect to the array and which are configured to couple to a respective plurality of IC chip dice on a contact surface of the IC chip die. Each of the plurality of conductive leadframes includes a plurality of chip-pin connections configured to conductively couple to bond pads of the IC chip die via conductive lead wires. The leadframe system further includes a support beam that extends across the respective one of the plurality of conductive leadframes along the contact surface of the IC chip die to enable support of the IC chip die to the respective one of the plurality of conductive leadframes at a plurality of support locations during testing of the IC associated with the IC chip die.

### BRIEF DESCRIPTION OF THE DRAWINGS

FIG. 1 illustrates an example diagram of a conductive leadframe.

FIG. 2 illustrates an example of a conductive leadframe.

FIG. 3 illustrates an example diagram of a conductive leadframe for testing an associated IC.

FIG. 4 illustrates an example diagram of a conductive leadframe array.

FIG. 5 illustrates an example of a conductive leadframe array.

### DETAILED DESCRIPTION

This disclosure relates generally to electronic system fabrication, and more specifically to an integrated circuit chip fabrication leadframe. The leadframe corresponds to a conductive leadframe that can be implemented in fabrication of an integrated circuit (IC) chip to provide chip-pins for the resultant IC chip package. The conductive leadframe can be formed from a unitary conductive material, and can be provided in an array of conductive leadframes for fabrication of a plurality of IC chips, such that the array of conductive leadframes can be collectively formed from the unitary conductive material.

The conductive leadframe includes chip-pin connections that can be electrically coupled to the IC chip die via conductive lead wires that connect the chip-pin connections to bond pads associated with the IC chip die. The chip-pin connections can subsequently be mechanically trimmed from the conductive leadframe to form the chip-pins of the resultant IC chip package. As an example, the IC chip die can contact the conductive leadframe on a contact surface (e.g., bottom surface), such that the chip-pins can extend orthogonally with respect to edges of the IC chip die, with the edges forming orthogonal edges of the contact surface. The chip-pin connections can thus be mechanically trimmed from the conductive leadframe to facilitate testing of the IC, such as via a strip handler. As an example, the strip handler can implement parallel testing of a plurality of ICs by providing conductive contact with the resultant chip-pins of each of the ICs concurrently and implementing a test protocol on each of the ICs concurrently.

The conductive leadframe also includes a support beam that extends along the contact surface across a length of the IC chip die, such as between a first edge of the IC chip die and a second edge of the IC chip die opposite the first edge. The support beam thus provides supporting of the IC chip die during testing of the IC subsequent to the trimming of the chip-pin connections from the conductive leadframe. As an example, the support beam can be coupled to one of the chip-pin connections that remains untrimmed during the testing of the IC. Therefore, the IC chip die can be supported at three support locations during the testing of the IC. One of the support locations can be associated with the untrimmed one of the chip-pin connections (e.g., a ground connection), while the other two support locations can be associated with opposite ends of the support beam proximal to the first and second edges of the IC chip die. Accordingly, based on the IC chip die having multiple supporting points during testing of the IC, parallel testing of multiple ICs can occur with mitigation of pivoting of the IC chip die resulting in loss of conductive contact, such as can occur in typical IC parallel testing in which the IC chip die is supported at only a single supporting point.

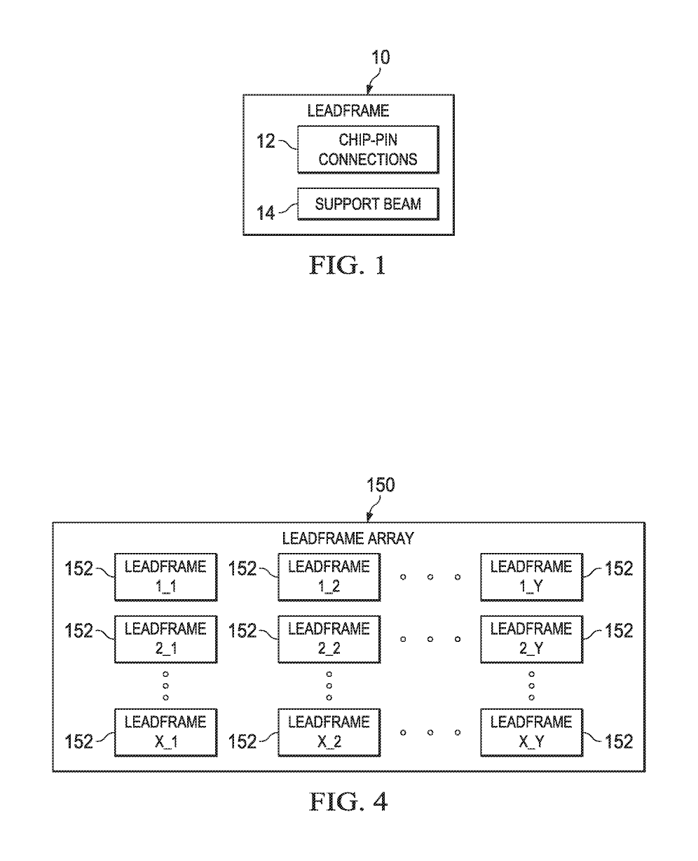

FIG. 1 illustrates an example diagram of a conductive leadframe 10. The conductive leadframe 10 can correspond to a unitary conductive material that is implemented to form chip-pins for an integrated circuit (IC) chip package. As an example, the conductive leadframe 10 can correspond to a Chip-On-Lead leadframe, such as for fabricating an SOT-23 6-pin IC chip. As described in greater detail herein, the conductive leadframe can be provided in an array of conductive leadframes to facilitate mass fabrication of IC chip packages, as well as parallel testing of the respective IC chip packages.

The conductive leadframe 10 includes chip-pin connections 12 and a support beam 14. The chip-pin connections 12 can be electrically coupled to an IC chip die that is associated with the resulting IC chip package, such as via conductive lead wires that connect the chip-pin connections 12 to bond pads associated with the IC chip die. The chip-pin connections 12 can subsequently be mechanically trimmed from the conductive leadframe 10 to form the chip-pins of the resultant IC chip package. As an example, the IC chip die can contact the conductive leadframe 10 on a contact surface. As described herein, the term “contact surface” with respect to the associated IC chip die corresponds to a flat, broad surface of the IC chip die that is in contact with the conductive leadframe 10 (e.g., a bottom surface).

Therefore, the chip-pins that result from the trimmed chip-pin connections 12 can extend orthogonally with respect to edges of the IC chip die. The chip-pin connections 12 can thus be mechanically trimmed from the conductive leadframe 10 to facilitate testing of the resulting IC, such as via a strip handler. As described herein in greater detail, the strip handler can implement parallel testing of a plurality of ICs by providing conductive contact with the resultant chip-pins and implementing a test protocol on each of the ICs concurrently.

The support beam 14 can extend along the contact surface across a length of the associated IC chip die, such as between a first edge of the IC chip die and a second edge of the IC chip die opposite the first edge. The support beam 14 can thus provide supporting of the associated IC chip die during testing of the resultant IC subsequent to the trimming of the chip-pin connections 12 from the conductive leadframe 10 to provide the chip-pins. As an example, the support beam 14 can be coupled to a single one of the chip-pin connections 12 that remains untrimmed during the testing of the resultant IC. Therefore, the associated IC chip die can be supported at three support locations during the testing of the IC, at least two of which are provide adjacent ends of the support beam 14.

One of the support locations can be associated with the untrimmed one of the chip-pin connections 12, which can correspond to a ground connection, while the other two support locations can be associated with opposite ends of the support beam 14 proximal to the first and second edges of the associated IC chip die. Accordingly, based on the associated IC chip die having multiple supporting points during testing of the resultant IC, such as with only a single chip-pin connection 12 coupled to ground, parallel testing of multiple ICs can occur, such that pivoting of the associated IC chip die can be mitigated. Such pivoting can result in loss of electrical connectivity of the tester and the associated chip-pins, which can thus result in a failed test of the resultant IC. Accordingly, pivoting of the resulting IC chip die can be mitigated during testing based on having multiple support locations for only a single chip-pin connection 12 being coupled to ground, as opposed to typical IC parallel testing in which the IC chip die may be supported at only a single supporting point (e.g., the ground connection).

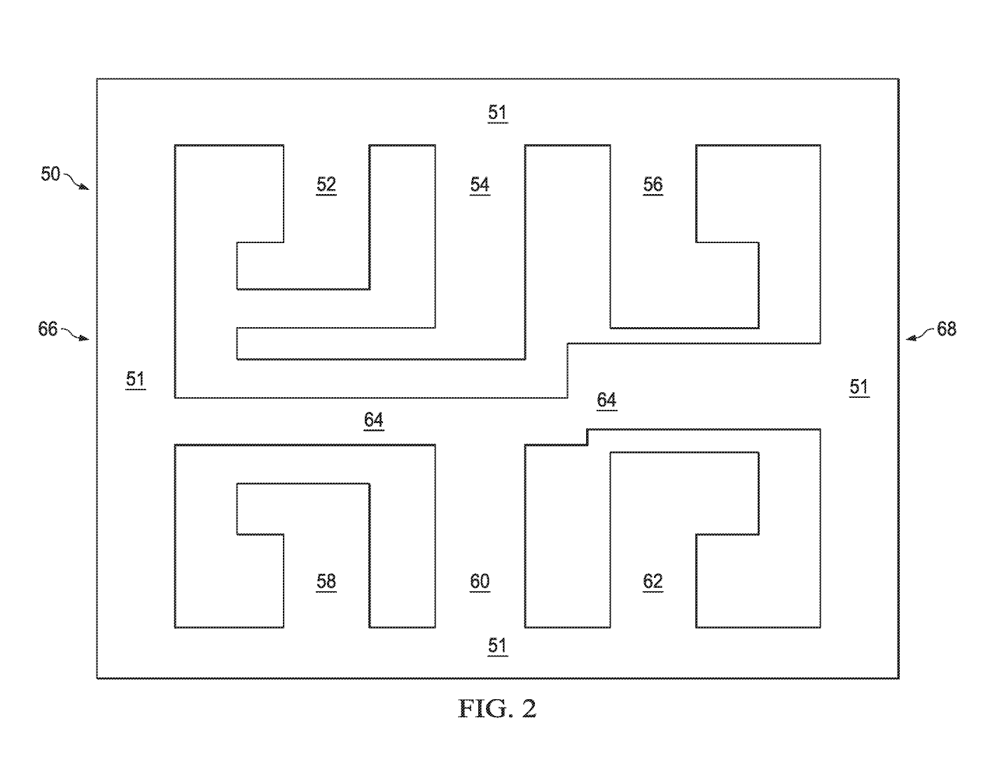

FIG. 2 illustrates an example of a conductive leadframe 50. In the example of FIG. 2, the conductive leadframe 50 can correspond to a Chip-On-Lead leadframe, such as for fabricating an SOT-23 6-pin IC chip. The conductive leadframe 50 is demonstrated as a substantially flat unitary conductive material having an outer frame 51 and including chip-pin connections 52, 54, 56, 58, 60, and 62 that extend inward from the outer frame 51. The conductive leadframe 50 also includes a support beam 64.

As described previously, the chip-pin connections 52, 54, 56, 58, 60, and 62 can be respectively electrically coupled to an IC chip die that is associated with the resulting IC chip package. For example, the chip-pin connections 52, 54, 56, 58, 60, and 62 can be electrically coupled to bond pads associated with the IC chip die via conductive lead wires. Additionally, the chip-pin connections 52, 54, 56, 58, 60, and 62 can subsequently be mechanically trimmed from the conductive leadframe 50 to form the chip-pins of the resultant IC chip package.

The support beam 64 is demonstrated as extending from a first end 66 of the outer frame 51 of the conductive leadframe 50 to a second end 68 of the outer frame 51 conductive leadframe 50. Therefore, the support beam 64 can extend along the contact surface across a length of the associated IC chip die, such as between a first edge of the IC chip die and a second edge of the IC chip die opposite the first edge. For example, the support beam 14 is dimensioned and configured to extend across the leadframe 50 a length that is at least commensurate (e.g., slightly longer than) the IC chip die that is to disposed thereon to form a corresponding IC. The conductive leadframe 50 can be fabricated such that the chip-pin connection 54 is slightly offset from a center-line across the conductive leadframe 50 to accommodate the support beam 64. Additionally, in the example of FIG. 2, the chip-pin connection 60 is coupled to the support beam 64, such that the chip-pin connection 60 extends between the outer frame 51 and the support beam 64.

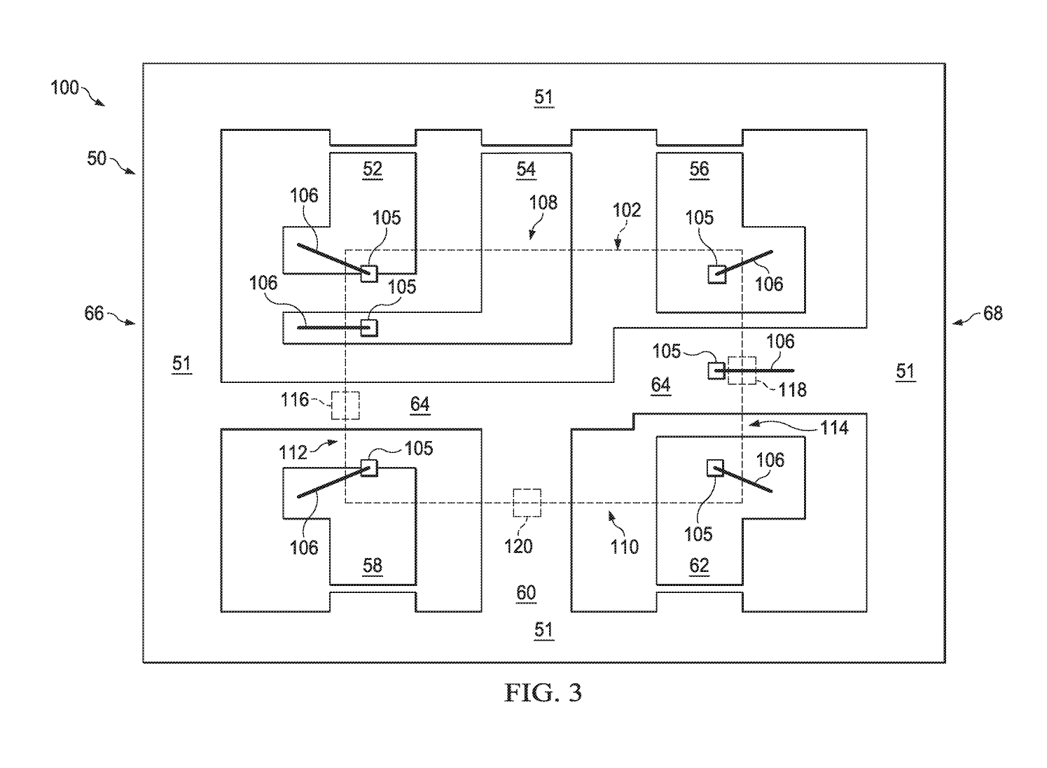

FIG. 3 illustrates an example diagram 100 of the conductive leadframe for testing the associated IC. The conductive leadframe in the diagram 100 is demonstrated as the conductive leadframe 50. Therefore, reference is to be made to the example of FIG. 2 in the following description of the example of FIG. 3, and like reference numbers are used in the example of FIG. 3 as those used in the example of FIG. 2.

The diagram 100 includes an outline of an IC chip die 102, demonstrated as a dashed line, that can be enclosed in an IC chip package. The IC chip die 102 includes bond pads 105 that are each conductively coupled to a respective one of the chip-pin connections 52, 54, 56, 58, 60, and 62 via a respective conductive lead wire 106. At this stage, the IC chip die 102 can be covered with a molding material within the associated IC chip package, subsequent to the coupling of the chip-pin connections 52, 54, 56, 58, 60, and 62 via the respective conductive lead wires 106, and thus prior to the testing of the associated IC. Alternatively, the IC chip die 102 can be covered with the molding material within the associated IC chip package subsequent to the testing of the associated IC. Additionally, in the example of FIG. 3, the chip-pin connections 52, 54, 56, 58, and 62 are demonstrated as having been machine trimmed from the conductive leadframe 50. Therefore, the chip-pin connections 52, 54, 56, 58, and 62 are no longer conductively coupled to the conductive leadframe 50 to form associated chip-pins for the associated IC chip package. Accordingly, the electrical isolation of the chip-pin connections 52, 54, 56, 58, and 62 can facilitate testing of the associated IC. The resulting chip-pins associated with the chip-pin connections 52, 54, 56, 58, 60, and 62, subsequent to fabrication of the associated IC chip package, extend outward orthogonally from a first peripheral edge 108 and a second peripheral edge 110 that is spaced apart from and opposite the first edge 110 by respective edges 114 and 116.

In the example of FIG. 3, the chip-pin connection 60 remains untrimmed from the conductive leadframe 50, and thus conductively coupled to the conductive leadframe 50. As an example, the chip-pin connection 60 can be machine trimmed from the conductive leadframe 50 subsequent to the testing of the associated IC. For example, the resultant chip-pin associated with the chip-pin connection 60 can correspond to a ground-pin for the associated IC chip package, such that, during testing of the associated IC, the conductive leadframe 50 can be grounded. Therefore, the chip-pin connection 60 can correspond to a single ground connection for the associated IC during testing, as well as subsequent to fabrication of the associated IC chip package.

As described previously, the support beam 64 is demonstrated as extending from a first end 66 of the outer frame 51 of the conductive leadframe 50 to a second end 68 of the outer frame 51 conductive leadframe 50. Therefore, the support beam 64 extends along the contact surface across a length of the associated IC chip die 102 (e.g. along a substrate), such as between a third and fourth edges 112 and 114 of the IC chip die 102. The third and fourth edges 112 and 114 thus interconnect the first and second edge 108 and 110. Therefore, in the example of FIG. 3, the diagram 100 demonstrates a first support location 116, a second support location 118, and a third support location 120. The first support location 116 is provided adjacent to a first end of the support beam 64, proximal to the outer frame 51 and to the third edge 112 of the IC chip die 102. The second support location 118 is provided adjacent to a second end of the support beam 64, proximal to the outer frame 51 and to the fourth edge 114 of the IC chip die 102. The third support location 120 is provided at the chip-pin connection 60, which is connected with the support beam 64, proximal to the outer frame 51 and to the second edge 110 of the IC chip die 102. As described herein, the edges 108, 110, 112, and 114 can refer to the edges of the IC chip die 102, or to respective edges of the associated IC chip package with respect to the proximity of the support locations 116, 118, and 120.

Based on the IC chip die 102 having the three support locations 116, 118, and 120 during testing of the associated IC, the placement of the IC chip die 102 can be afforded increased stability with respect to the conductive leadframe 50. Therefore, test equipment that is provided to concurrently contact the chip-pins associated with the chip-pin connections 52, 54, 56, 58, 60, and 62 can maintain contact with all of the chip-pins based on the stability provided via the three support locations 116, 118, and 120. By contrast, other typical leadframe designs may include only a single support location (e.g., a single chip-pin connection), and thus can experience pivoting about that single support location as a result of a less stable connection of the IC chip die to the conductive leadframe. Such pivoting can result in a loss of connectivity of the testing leads to the chip-pins, and thus a failed test. Accordingly, the conductive leadframe 50 disclosed herein can provide a more stable testing environment in fabrication of IC chip packages.

FIG. 4 illustrates an example of a conductive leadframe array 150. The conductive leadframe array 150 includes a plurality of conductive leadframes 152 arranged in an array. The conductive leadframe array 150 includes a plurality X of rows of conductive leadframes 152, and a plurality Y of columns of conductive leadframes 152, where X and Y are each positive integers. Each of the conductive leadframes 152 can be arranged substantially the same, and can each be configured to receive a respective IC chip die, such as similar to the IC chip die 102 in the example of FIG. 3. Therefore, each of the conductive leadframes 152 in the conductive leadframe array 150 can include a plurality of chip-pin connections and a support beam, similar to as described previously in the examples of FIGS. 1-3. As an example, the conductive leadframe array 150 can be formed from a single unitary conductive material, such that the conductive leadframe array 150 is monolithically formed.

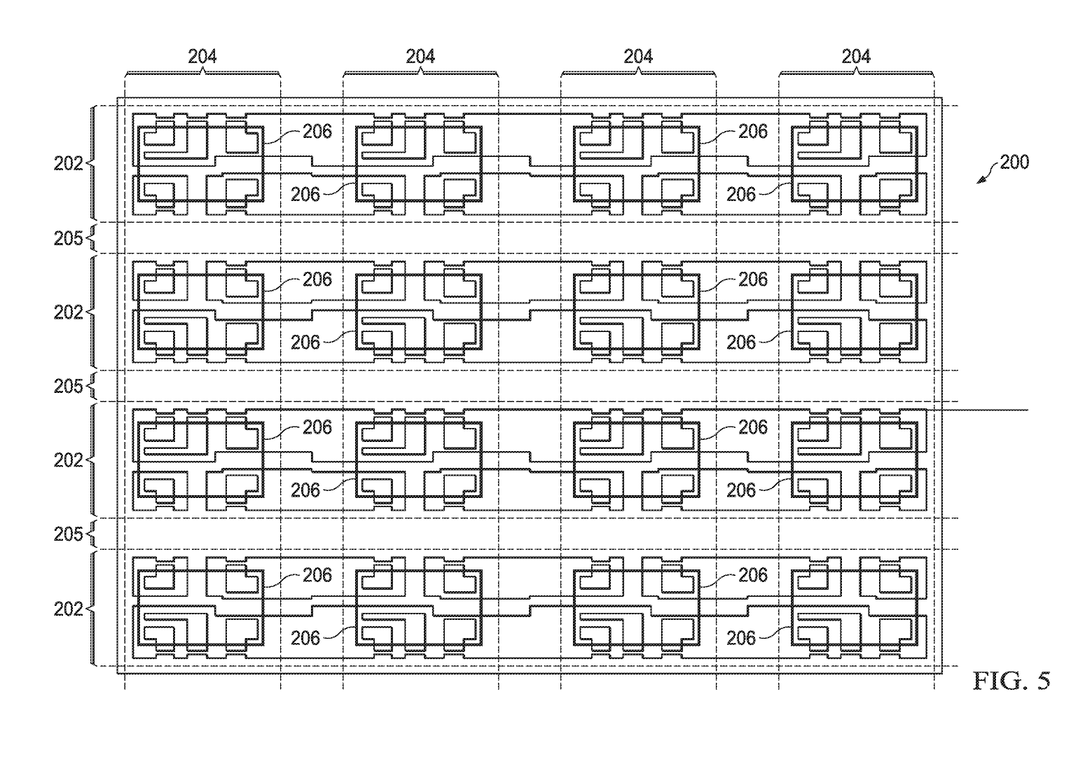

FIG. 5 illustrates an example of a conductive leadframe array 200. The conductive leadframe array 200 includes a plurality of conductive leadframes arranged in an array. The conductive leadframe array 200 includes a plurality of rows 202 of conductive leadframes, and a plurality of columns 204 of conductive leadframes. While the conductive leadframe array 200 demonstrates a total of sixteen conductive leadframes in the rows 202 and the columns 204, it is to be understood that the conductive leadframe array 200 can include more or less conductive leadframes in a given array. Each of the conductive leadframes in the array 200 is demonstrated as arranged substantially the same, with every other one of the rows 202 being a mirror image of adjacent row(s) 202. Alternatively or additionally, every other one of the columns 204 can be a mirror image of adjacent column(s) 204. In the example of FIG. 5, the rows 202 are separated by a dividing beam 205 that extends along and between the rows 202. While the columns 204 are demonstrated as not being divided by a similar dividing beam, it is to be understood that the columns can be divided by a dividing beam (not shown) that extends along and between the columns 204, such as to form the outer frame 51 around each of the conductive leadframes.

Each of the conductive leadframes in the conductive leadframe array 200 can be arranged substantially the same as the conductive leadframe 50 in the example of FIG. 3. Therefore, each of the conductive leadframes in the conductive leadframe array 200 can include a plurality of chip-pin connections and a support beam, similar to the support beam 64 as described previously in the examples of FIGS. 2 and 3. As also demonstrated in the example of FIG. 5, the support beam extends laterally as a continuous conductive structure through each leadframe in each respective row 202. One or more chip-pin connections in each leadframe can extend from the outer frame (transversely to the direction of the support beam) and connect to the support beam to provide additional mechanical support, as disclosed herein. In the example of FIG. 5, all but one of the chip-pin connections in each of the conductive leadframes are demonstrated as machine trimmed, such as provided during testing of the associated ICs similar to the example of FIG. 3, to provide a single ground connection (e.g., the chip-pin connection 60 provided in the example of FIG. 3) to the respective conductive leadframe.

Each of the conductive leadframes in the rows 202 and the columns 204 is demonstrated as receiving a respective IC chip package 206. The support beam thus provides support at two or more (e.g., three) locations along the periphery of the IC chip package 206. In the example of FIG. 5, the conductive leadframe array 200 is monolithically formed, such that the entire conductive leadframe array 200 is formed from a single unitary conductive material. For example, the conductive leadframe array 200 can be formed from a sheet of electrically conductive material that is mechanically or chemically etched and/or machined to provide a predetermined pattern to form the associated respective conductive leadframes in the rows 202 and columns 204. Additionally, during testing of the respective ICs associated with the IC chip packages, the unitary material of the conductive leadframe array 200 can be grounded, such that each of the ICs is demonstrated to have a single ground connection (e.g., the chip-pin connection 60 provided in the example of FIG. 3).

As an example, during testing of the associated ICs associated with each of the conductive leadframes, a parallel test fixture (e.g., a strip handler) can be applied to a given row 202, column 204, or multiple leadframe portion the conductive leadframe array 200 to provide parallel testing of the associated ICs. Because each of the conductive leadframes in the conductive leadframe array 200 can include a plurality of supporting locations (e.g., three supporting locations, as described previously in the example of FIG. 3), pivoting of the conductive leadframes out of conductive contact with the associated pins can be substantially mitigated during the parallel testing of the associated conductive leadframes.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications, and variations that fall within the scope of this application, including the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements.

What is claimed is:

1. A conductive leadframe configured to couple to an integrated circuit (IC) chip die on a contact surface of the IC chip die, the conductive leadframe comprising:
a plurality of chip-pin connections configured to conductively couple to bond pads of the IC chip die via conductive lead wires; and
a support beam that extends across the conductive leadframe along the contact surface of the IC chip die to enable support of the IC chip die with respect to the conductive leadframe at a plurality of support locations during testing of the IC associated with the IC chip die.

2. The conductive leadframe of claim 1, wherein the support beam is coupled to one of the plurality of chip-pin connections.

3. The conductive leadframe of claim 2, wherein the respective one of the plurality of chip-pin connections comprises one of the plurality of support locations during testing of the IC.

4. The conductive leadframe of claim 1, wherein the plurality of support locations comprises:
a first support location proximal to a first edge of the IC chip die;
a second support location proximal to a second edge of the IC chip die that is opposite the first edge; and
a third support location proximal to a third edge that extends orthogonally between the first and second edges.

5. The conductive leadframe of claim 4, wherein the third support location is located along one of the plurality of chip-pin connections that remains untrimmed from the conductive leadframe during testing of the IC associated with the IC chip die.

6. The conductive leadframe of claim 1, wherein the plurality of chip-pin connections are arranged in contact with the contact surface of the IC chip die, such that the plurality of chip-pin connections are arranged to be machine-trimmed from the conductive leadframe to provide a respective plurality of chip-pins extending orthogonally relative to a first edge of the IC chip die and a second edge of the IC chip die that is opposite the first edge.

7. The conductive leadframe of claim 6, wherein the support beam extends along the contact surface of the IC chip die between a third edge the IC chip die and a fourth edge of the IC chip die opposite the third edge, the third and fourth edges being spaced apart and substantially parallel with respect to each other and extending between the first and second edges.

8. The conductive leadframe of claim 6, wherein one of the plurality of chip-pin connections corresponds to one of the plurality of support locations during testing of the IC subsequent to a remaining plurality of chip-pin connections being machine-trimmed.

9. The conductive leadframe of claim 1, wherein the conductive leadframe is configured as a Chip-On-Lead leadframe.

10. A plurality of conductive leadframes comprising the conductive leadframe of claim 1, wherein the plurality of conductive leadframes are arranged in an array and are fabricated from a unitary conductive material with respect to the array, wherein each of the plurality of conductive leadframes is configured to couple to a respective IC chip die on a contact surface of the IC chip die and comprises:
a plurality of chip-pin connections configured to conductively couple to bond pads of the IC chip die via respective conductive lead wires; and
a support beam that extends across the respective one of the plurality of conductive leadframes along the contact surface of the IC chip die to enable support of the IC chip die to the respective one of the plurality of conductive leadframes at a plurality of support locations during testing of the IC associated with the IC chip die.

11. The plurality of conductive leadframes of claim 10, wherein the support beam associated with each of the plurality of conductive leadframes corresponds to a single support beam associated with each conductive leadframe of a row of the plurality of conductive leadframes in the array, such that the single support beam extends along the contact surface of each conductive leadframe of the row of the plurality of conductive leadframes in the array.

12. A conductive leadframe configured to couple to an integrated circuit (IC) chip die on a contact surface of the IC chip die, the conductive leadframe comprising:
a plurality of chip-pin connections configured to conductively couple to bond pads of the IC chip die via conductive lead wires; and
a support beam that extends across the conductive leadframe along the contact surface of the IC chip die between a first edge of the IC chip die and a second edge of the IC chip die opposite the first edge to enable support of the IC chip die to the conductive leadframe at a junction of the contact surface and the first edge and at a junction of the contact surface and the second edge during testing of the IC associated with the IC chip die.

13. The conductive leadframe of claim 12, wherein the support beam is coupled to one of the plurality of chip-pin connections to enable support of the IC chip die to the conductive leadframe at a junction of the contact surface and a third edge that extends between the first edge and the second edge during testing of the IC associated with the IC chip die.

14. The conductive leadframe of claim 12, wherein the plurality of chip-pin connections are arranged in contact with the contact surface of the IC chip die, such that the plurality of chip-pin connections are arranged to be machine-trimmed from the conductive leadframe to provide a respective plurality of chip-pins extending orthogonally relative to a third edge and a fourth edge of the IC chip die, the third and fourth edges being spaced apart and parallel with respect to each other and extending between the first and second edges.

15. The conductive leadframe of claim 14, wherein one of the plurality of chip-pin is configured to enable support of the IC chip die to the conductive leadframe at a junction of the contact surface and the third edge, which extends between the first edge and the second edge, during testing of the IC subsequent to a remaining plurality of chip-pin connections being machine-trimmed.

16. A plurality of conductive leadframes comprising the conductive leadframe of claim 12, wherein the plurality of conductive leadframes are arranged in an array and are fabricated from a unitary conductive material with respect to the array, wherein each of the plurality of conductive leadframes is configured to couple to a respective IC chip die on a contact surface of the IC chip die and comprises:
a plurality of chip-pin connections configured to conductively couple to bond pads of the IC chip die via respective conductive lead wires; and
a support beam that extends across the respective one of the plurality of conductive leadframes along the contact surface of the IC chip die between a first edge of the IC chip die and a second edge of the IC chip die opposite the first edge to enable support of the IC chip die to the respective one of the plurality of conductive leadframes at a junction of the contact surface and the first edge and at a junction of the contact surface and the second edge during testing of the IC associated with the IC chip die.

17. A leadframe system comprising a plurality of conductive leadframes that are arranged in an array and are fabricated from a unitary conductive material with respect to the array and which are configured to couple to a respective plurality of integrated circuit (IC) chip dice on a contact surface of the IC chip die, each of the plurality of conductive leadframes comprising:
a plurality of chip-pin connections configured to facilitate conductive coupling to bond pads of the IC chip die via conductive lead wires; and
a support beam that extends across the respective one of the plurality of conductive leadframes along the contact surface of the IC chip die to enable support of the IC chip die to the respective one of the plurality of conductive leadframes at a plurality of support locations during testing of the IC associated with the IC chip die.

18. The system of claim 17, wherein the support beam associated with each of the plurality of conductive leadframes corresponds to a single support beam associated with each conductive leadframe of a row of the plurality of conductive leadframes in the array, such that the single support beam extends across the contact surface of each conductive leadframe of the row of the plurality of conductive leadframes in the array.

19. The system of claim 17, wherein the plurality of support locations associated with each of the plurality of conductive leadframes comprises:
a first support location proximal to a first edge of the respective one of the plurality of IC chip dice;
a second support location proximal to a second edge of the respective one of the plurality of IC chip dice that is opposite the first edge; and
a third support location proximal to a third edge that extends orthogonally between the first and second edges.

20. The system of claim 19, wherein the third support location is located along one of the plurality of chip-pin connections that remains untrimmed from the conductive leadframe during testing of the respective IC associated with the respective one of the plurality of IC chip dice.
